(19) United States
(12) Patent Application Publication
(10) Pub. No.: US 2024/0178104 A1
(43) Pub. Date: May 30, 2024

(54) LEADFRAME BASED POWER MODULE

(71) Applicant: TEXAS INSTRUMENTS INCORPORATED, Dallas, TX (US)

(72) Inventors: MAKOTO SHIBUYA, Tokyo (JP); DAIKI KOMATSU, Beppu (JP); MASAMITSU MATSUURA, Beppu (JP)

(21) Appl. No.: 18/070,530

(22) Filed: Nov. 29, 2022

(51) Int. Cl. H01L 23/495; H01L 21/56; H01L 23/31

(52) U.S. Cl. CPC H01L 23/49541; H01L 21/56; H01L 23/3107; H01L 28/10

(57) ABSTRACT

An electronic device includes a leadframe that includes pins, where the pins have a proximate end and a distal end. A die is attached to the proximate end of the pins of the leadframe and a mold compound encapsulates the die. An electronic component is attached to the leadframe. The distal end of at least two of the pins are substantially perpendicular to the proximate end of the pins in a first direction and the distal end of the remaining pins are substantially perpendicular to the proximate end of the pins in a second direction that is opposite that of the first direction.

### TECHNICAL FIELD

The present disclosure relates to an electronic device and more specifically, to a leadframe based power module with a reduced footprint.

### BACKGROUND

Miniaturization of semiconductor products, especially highly integrated power module packages, has become more and more important. For example, a need to reduce the physical footprint in an X-Y direction of semiconductor products in the portable device market (e.g., smart phones, tablets, PC,s, etc.) has increased due to a need for smaller, more efficient, and less expensive portable devices. As an example, power modules (e.g., DC/DC converters) normally include a power control integrated circuit, inductors, capacitors, resistors, etc. Because of the number of components more space is needed. As a result, there is a need for an integrated power module package having a small physical footprint and that is suitable for mass production.

### SUMMARY

In described examples, an electronic device includes a leadframe that includes pins, where the pins have a proximate end and a distal end. A die is attached to the proximate end of the pins of the leadframe and a mold compound encapsulates the die. An electronic component is attached to the leadframe. The distal end of at least two of the pins are substantially perpendicular to the proximate end of the pins in a first direction and the distal end of the remaining pins are substantially perpendicular to the proximate end of the pins in a second direction that is opposite that of the first direction.

In another described example, a method includes providing a leadframe having pins that includes a proximate end and a distal end. A die is attached to the proximate end of the pins and a mold compound is formed over the die. The distal end of at least two pins are formed substantially perpendicular to the proximate end of the at least two pins in a first direction and the distal end of the remaining pins are formed substantially perpendicular to the proximate end of the remaining pins in a second direction, where the second direction is opposite to the first direction. An electronic component is attached to the proximate end of the at least two pins on a side of the leadframe that is opposite to that of the die.

In still another described example, a method of fabricating electronic devices includes providing an array of leadframes, each leadframe of the array of leadframes having inner pins comprised of a proximate end and a distal end and outer pins comprised of a proximate end, a distal end, and a tie bar connection end, the leadframes being connected to each other via a first tie bar connected to the distal end of the inner and outer pins and a second tie bar connected to the tie bar connection end of the outer pins to form the array. Dies are attached to the proximate end of the pins and a mold compound is formed over the dies. The first tie bar is removed from the distal end of the inner and outer pins via a first punch die process. The distal end of the outer pins is formed substantially perpendicular to the proximate end of the inner and outer pins in a first direction and the distal end of the inner pins is formed substantially perpendicular to the proximate end of the inner and outer pins in a second direction, where the second direction being opposite to the first direction. Electronic components are attached to an exposed surface of mounting surface portions of the outer pins on a side of the leadframes that is opposite that of the dies. The second tie bar is removed from the tie bar connection end of the outer pins via a second punch die process and the tie bar connection end of the outer pins is trimmed.

### BRIEF DESCRIPTION OF THE DRAWINGS

FIG. 1 illustrates a perspective view of an example electronic device.

FIG. 2 illustrates a plan view of the example electronic device of FIG. 1.

FIGS. 3 and 4 illustrate top and cross section views respectively of a leadframe in the early stages of fabrication of the electronic device of FIGS. 1 and 2.

FIGS. 5 and 6 illustrate top and cross section views respectively of the electronic device of FIGS. 3 and 4 after attachment of a die.

FIGS. 7 and 8 illustrate top and cross section views respectively of the electronic device of FIGS. 5 and 6 after formation of a mold compound.

FIGS. 9 and 10 illustrate top and cross section views respectively of the electronic device of FIGS. 7 and 8 after removal of a first tie bar.

FIGS. 11 and 12 illustrate top and cross section views respectively of the electronic device of FIGS. 9 and 10 after a formation of a distal end of some pins on the leadframe.

FIGS. 13 and 14 illustrate top and cross section views respectively of the electronic device of FIGS. 11 and 12 after a formation of a distal end of the remaining pins on the leadframe.

FIGS. 15 and 16 illustrate top and cross section views respectively of the electronic device of FIGS. 13 and 14 after the deposition of an adhesive.

FIGS. 17 and 18 illustrate top and cross section views respectively of the electronic device of FIGS. 15 and 16 after attachment of an electronic component on the leadframe.

FIGS. 19 and 20 illustrate top and cross section views respectively of the electronic device of FIGS. 17 and 18 after removal of a second tie bar.

FIGS. 21 and 22 illustrate top and cross section views respectively of the electronic device of FIGS. 19 and 20 after trimming of tie bar connection end of the pins of the leadframe.

### DETAILED DESCRIPTION

Miniaturization of semiconductor products, especially highly integrated power module packages, has become more and more important. For example, a need to reduce the physical footprint in an X-Y direction of semiconductor products in the portable device market (e.g., smart phones, tablets, PC,s, etc.) has increased due to a need for smaller, more efficient, and less expensive portable devices. As an example, power modules (e.g., DC/DC converters) normally include a power control integrated circuit, inductors, capacitors, resistors, etc. Because of the number of components more space is needed. As a result, there is a need for an integrated power module package having a small physical footprint and that is suitable for mass production.

Disclosed herein is an electronic device and more specifically, a power module package and method of fabricating the power module package that overcomes the challenges described above. The power module package utilizes a single in-line (SIP) type leadframe to reduce the physical footprint of the package. More specifically, the power module package includes an integrated control circuit attached to a proximate end of pins of a leadframe. The integrated control circuit is encapsulated in a mold compound. An electronic component is attached to the proximate end of the pins on an opposite side of the leadframe. A distal end of the pins of the leadframe are formed to be substantially perpendicular to the proximate end of the pins.

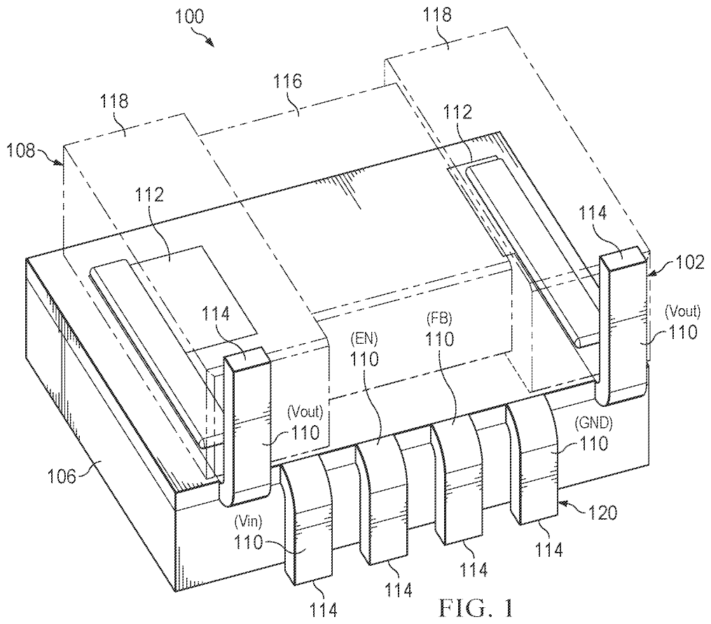

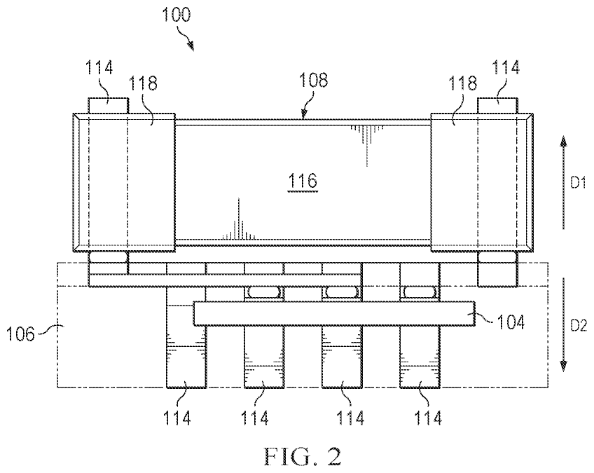

FIGS. 1 and 2 are perspective and plan views respectively of an example electronic device (e.g., power module package) 100 comprised of a leadframe 102, a die 104 attached to the leadframe 102 and encapsulated with a mold compound 106, and an electronic component (e.g., inductor) 108.

Although different types of leadframes can be used for the electronic device 100, for simplicity only, the leadframe described herein and illustrated in the figures is a single in-line (SIP) type leadframe. The leadframe 102 includes multiple pins 110 having various functions. In one example, the pins may be comprised of a power-good (PG) pin, an input voltage pin (Vin), an enable pin (EN), a feedback pin (FB), a ground pin (GND), and a voltage out pin (Vout). The pins 110 are comprised of a proximate end 112 and a distal end 114.

The die (e.g., flip chip) 104 may include an integrated control circuit to control the electronic device and other circuitry that is configured to receive and process signals from the electronic component 108 in an appropriate manner. The die 104 is connected to the proximate end 112 of the pins 110 via a conductive adhesive (e.g., solder) on one side of the leadframe 102. Thus, the proximate end 112 is defined as the portion of the pins 110 where the die 104 is mounted and the distal end 114 is the opposite portion of the pins 110 away from the die 104. The mold compound 106 encapsulates the die 104 and partially covers the proximate end 112 of the pins 110.

The electronic component 108 can be any type of component for use in a power module. For simplicity, the example electronic component 108 described herein and illustrated in the figures is an inductor. The inductor includes a center portion 116 made from a ferromagnetic material (e.g., nickel, ferromagnetic ceramics) attached to two end portions 118 made from an electrically conductive metal (e.g., tin). The electronic component 108 attaches to the proximate end 112 of the pins 110 on a side of the leadframe 102 opposite that of the die 104.

The distal end 114 of the pins 110 are arranged substantially perpendicular to the proximate end 112 of the pins 110. More specifically, some of the distal end 114 of the pins 110 extend substantially perpendicular is a first direction D1. The remaining distal end 114 of the pins 110 extend substantially perpendicular to the proximate end 112 of the pins in a second direction D2 where the second direction D2 is in an opposite direction to that of the first direction D1.

In the example illustrated in FIGS. 1 and 2, the distal end 114 of the two outside pins 110 (PG), 110 (Vout) extend in the first direction A1 toward the electronic component 108. The distal end 114 of the two outside pins 110 (PG), 110 (Vout) contact an outer side surface of each end portion 118 on the electronic component 108 and are therefore electrically coupled to the electronic component 108. The distal end 114 of the remaining four pins 110 (Vin), 110 (EN), 110 (FB), 110 (GND) extend in the second direction A2 toward the mold compound 106, but are separated from the mold compound 106 by a gap 120.

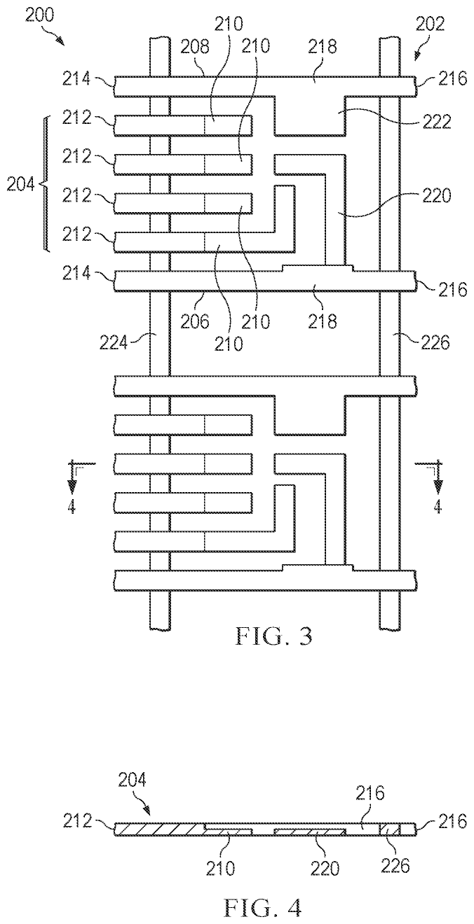

FIGS. 3-22 illustrate a fabrication process associated with the formation of the electronic device 100 illustrated in FIGS. 1 and 2. Though depicted sequentially as a matter of convenience, at least some of the actions shown can be performed in a different order and/or performed in parallel. Alternatively, some implementations may perform only some of the actions shown. Still further, although the example illustrated in FIGS. 3-22 is an example method illustrating the example configuration of FIGS. 1 and 2, other methods and configurations are possible. It is understood that although the method illustrated in FIGS. 3-22 depicts the fabrication process of a two electronic devices, the process applies to an array of electronic devices. Thus, after fabrication of the array of electronic device the array is singulated to separate each electronic device from the array. In addition, in the description to follow FIGS. 3, 5, 7, 9, 11, 13, 15, 17, 19, and 21 are top views of the fabricating process and FIGS. 4, 6, 8, 10, 12, 14, 16, 18, 20, and 22 are the corresponding cross section views of the fabricating process taken along line A-A in FIG. 3.

Referring to FIGS. 3 and 4, the fabrication process begins with an array 200 of leadframes comprised of individual leadframes 202. For simplicity, a single in-line (SIP) leadframe will be described herein and illustrated in the figures. It is to be understood, however, that other types of leadframes can be utilized in the described process. The SIP leadframes 202 includes four inner pins 204 and two outer pins 206, 208. The four inner pins 204 include a partially etched proximate end 210, and a distal end 212. The partially etched proximate end 210 has a thickness that is less than a thickness of the distal end 212 by approximately 40-60%. Both outer pins 206, 208 include a distal end 214, a tie bar connection end 216, and a mounting surface portion 218. In the example illustrated in the figures, one outer pin 206 further includes a partially etched proximate end 220 similar to that of the partially etched proximate end 210 of the four inner pins 204. The other outer pin 208 includes a proximate end 222 that is not partially etched. In other examples, however, the proximate end of the other outer pin 208 may be partially etched.

The individual leadframes 202 are connected together with a first tie bar 224 that connects the distal end 212, 214 of the inner and outer pins 204, 206, 208 together and a second tie bar 226 that connects the tie bar connection end 216 of the outer pins 206, 208 together. Thus, the first and second tie bars 224, 226 connect the individual leadframes 202 together to thereby form the array 200.

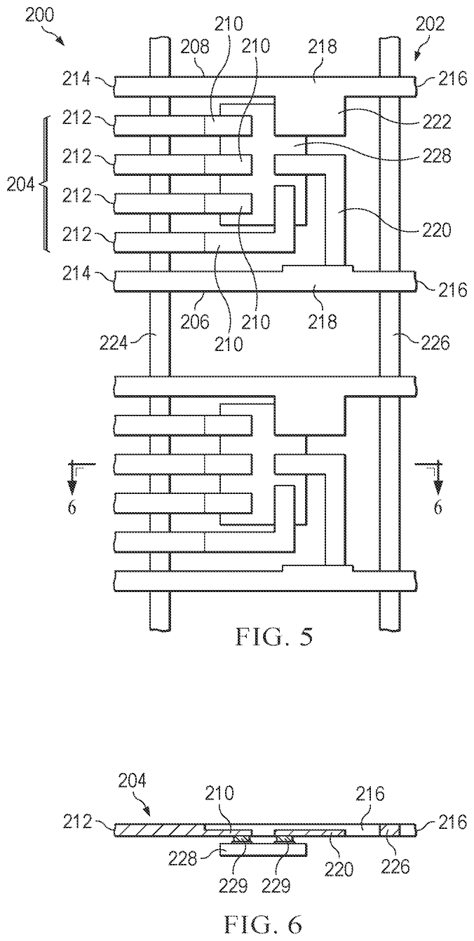

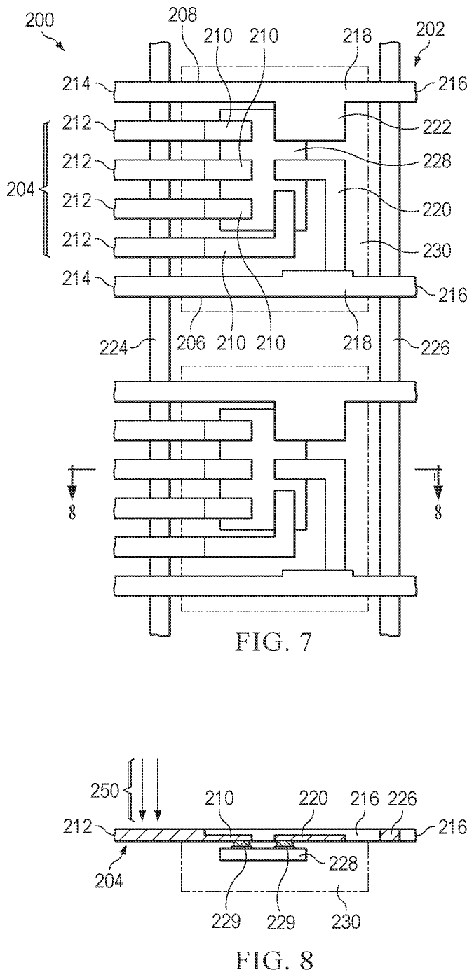

A die 228 is attached to the proximate end 210, 220, 222 of the inner and outer pins 204, 206, 208 via an adhesive (e.g., solder) 229 on one side of the leadframes 202 resulting in the configurations in FIGS. 5 and 6. A mold compound 230 is formed over the die 228 and encapsulates the die 228 resulting in the configuration in FIGS. 7 and 8. In addition, the mold compound 230 encapsulates the partially etched proximate end 210 of the four inner pins 204 and the partially etched proximate end 220 of the one outer pin 206. The mounting surface portions 218 of both outer pins 206, 208 and the proximate end 222 of the other outer pin 208 are not fully encapsulated by the mold compound 230. Rather, a surface of the mounting surface portions 218 and a surface of the proximate end 222 are substantially flush with a surface of the mold compound 230 and are thus exposed.

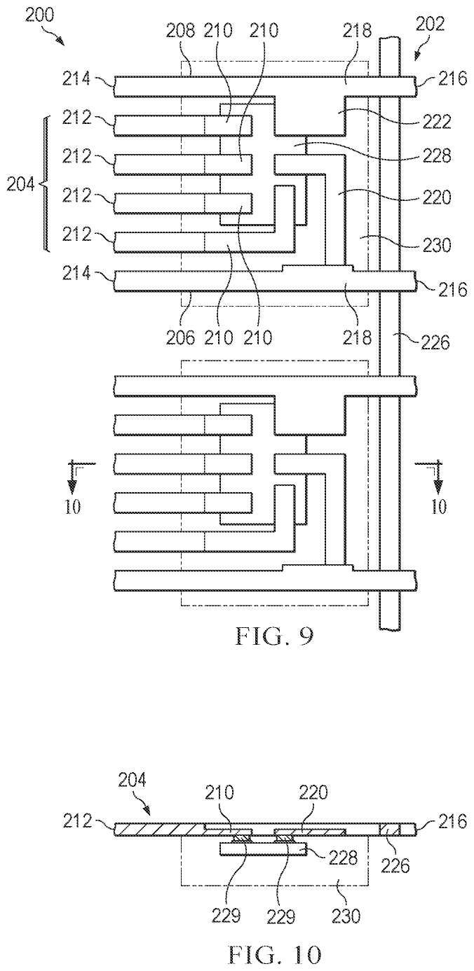

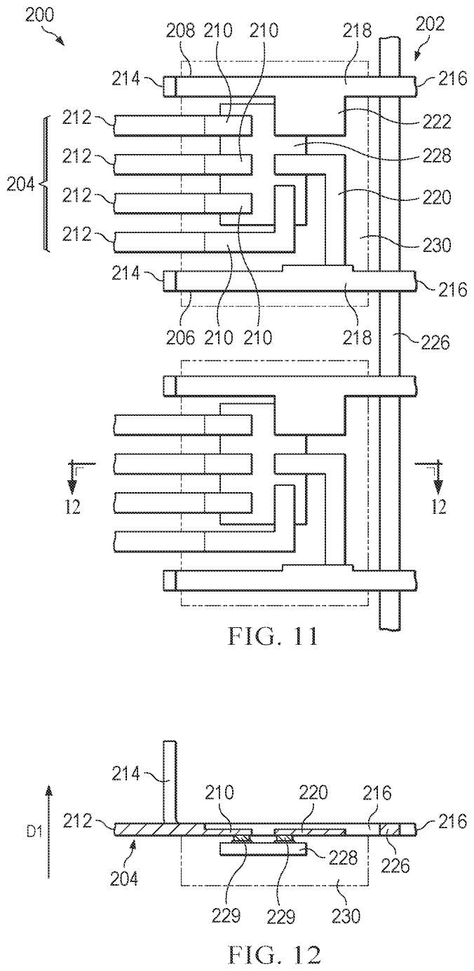

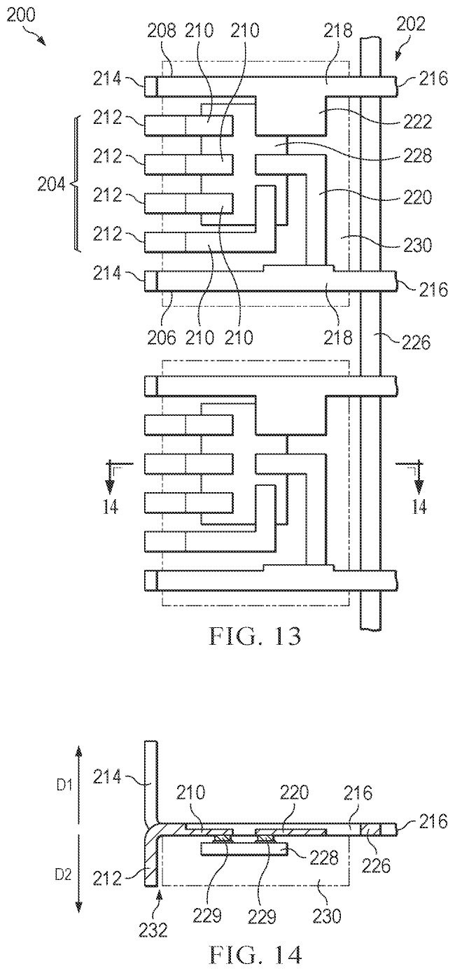

The first tie bar 224 is removed from the distal end 212, 214 of the inner and outer pins 204, 206, 208 via a first punch die process 250 resulting in the configuration of FIGS. 9 and 10. The distal end 214 of the outer pins 206, 208 are formed in a first direction D1 substantially perpendicular to the proximate end 210, 220, 222 of the inner and outer pins 204, 206, 208 resulting in the configuration in FIGS. 11 and 12. The distal end 212 of the four inner pins 204 are formed in a second direction D2 opposite that of the first direction D1 and substantially perpendicular to the proximate end 210 of the four inner pins 204 resulting in the configuration in FIGS. 13 and 14. The distal end 212 of the four inner pins 204 are formed such that the distal end 212 of the four inner pins 204 and the mold compound 230 are separated by a gap 232.

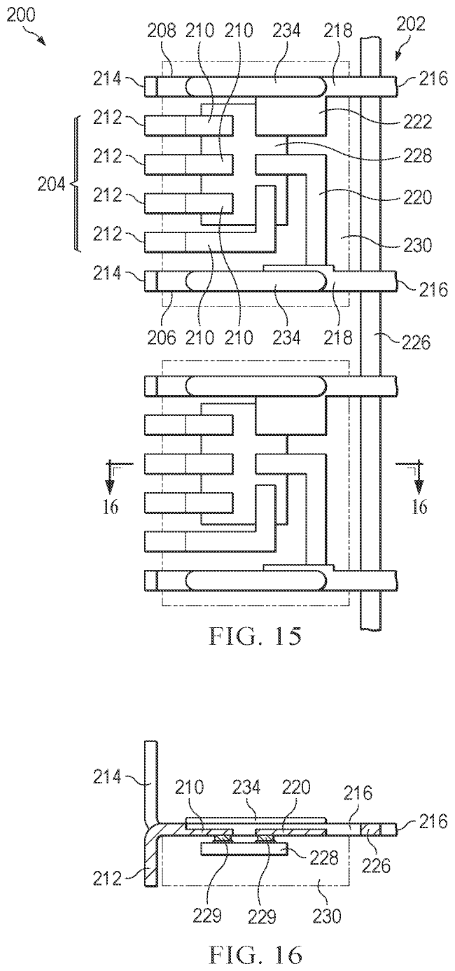

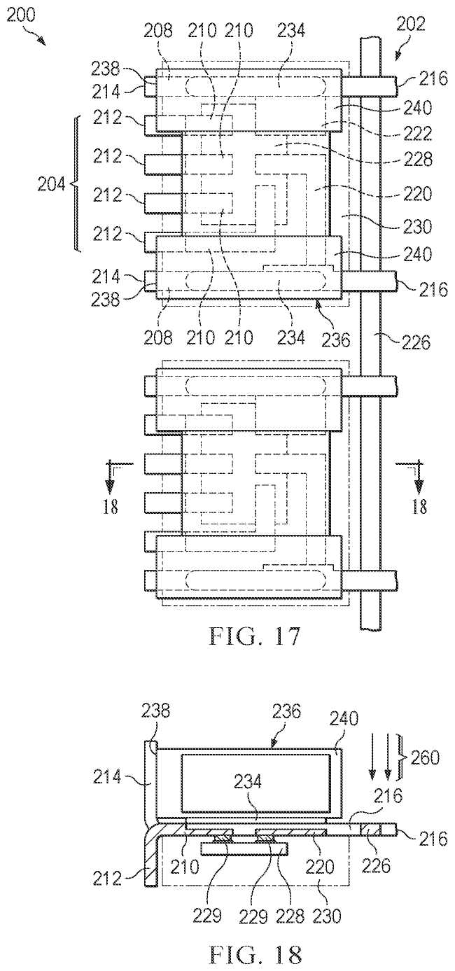

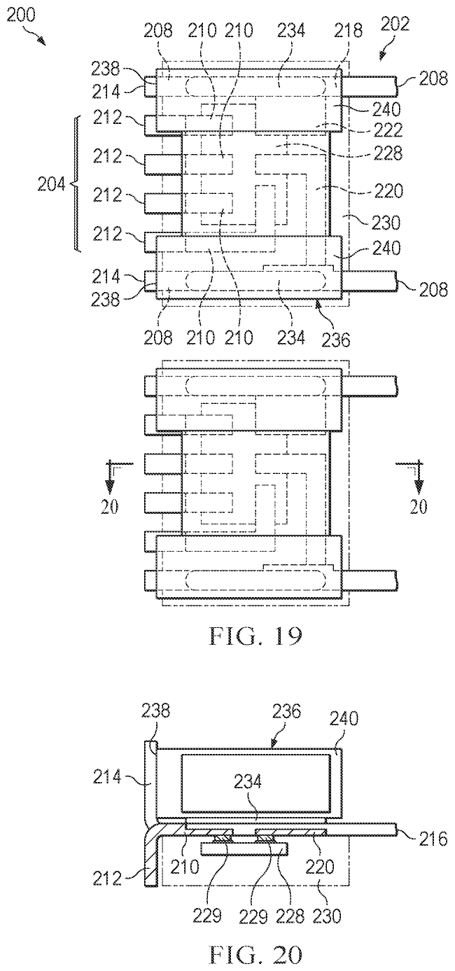

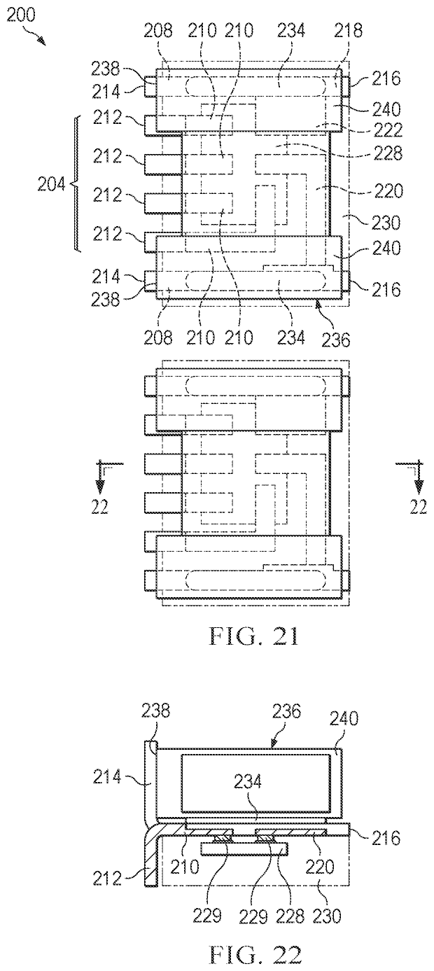

A conductive adhesive (e.g., solder) 234 is deposited on the exposed surface of the mounting surface portions 218 of the two outer pins 206, 208 resulting in the configuration in FIGS. 15 and 16. An electronic component 236 is placed on the adhesive 234 such that an outer surface 238 of end portions 240 contact the distal end 214 of the two outer pins 206, 208 resulting in the configuration in FIGS. 17 and 18. The second tie bar 226 is removed via a second punch die process 260 resulting in the configuration in FIGS. 19 and 20. The tie bar connection end 216 of the two outer pins 206, 208 are trimmed via a blade sawing process such that the tie bar connection end 216 of the two outer pins 206, 208 are substantially flush with the mold compound 230 resulting in the configuration in FIGS. 21 and 22.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a leadframe having pins, the pins having a proximate end and a distal end;
a die attached to the proximate end of the pins of the leadframe;
a mold compound encapsulating the die; and
an electronic component attached to the leadframe,
wherein the distal end of at least two of the pins are substantially perpendicular to the proximate end of the pins in a first direction and the distal end of remaining pins are substantially perpendicular to the proximate end of the pins in a second direction that is opposite that of the first direction.

2. The electronic device of claim 1, wherein the distal end of the at least two pins are electrically coupled to the electronic component.

3. The electronic device of claim 1, wherein the distal end of the remaining pins are separated from the mold compound by a gap.

4. The electronic device of claim 1, wherein the electronic component is attached to the proximate end of the pins on an opposite side of the leadframe as the die.

5. The electronic device of claim 1, wherein the electronic component is an inductor.

6. The electronic device of claim 5, wherein a surface of end portions of the inductor are in contact with the distal end of the at least two pins.

7. The electronic device of claim 1, wherein the die is a flip chip die.

8. The electronic device of claim 1, wherein the electronic device is a power module.

9. A method comprising:
providing a leadframe having pins comprised of a proximate end and a distal end;
attaching a die to the proximate end of the pins;
forming a mold compound over the die;
forming the distal end of at least two pins substantially perpendicular to the proximate end of the pins in a first direction;
forming the distal end of remaining pins substantially perpendicular to the proximate end of the pins in a second direction, the second direction being opposite to the first direction; and
attaching an electronic component to a mounting surface portion of the at least two pins on a side of the leadframe that is opposite to that of the die.

10. The method of claim 9, wherein forming a mold compound over the die includes forming the mold compound over the proximate end of the pins that are partially etched.

11. The method of claim 9, wherein forming the distal end of at least two pins substantially perpendicular to the proximate end of the pins in a first direction includes forming the distal end of two outer pins in the first direction.

12. The method of claim 11, wherein attaching an electronic component to the proximate end of the pins on a side of the leadframe that is opposite to that of the die includes attaching an inductor to the proximate end of the pins to contact the distal end of the two outer pins.

13. The method of claim 9, wherein forming the distal end of the remaining pins substantially perpendicular to the proximate end of the pins in a second direction, the second direction being opposite to the first direction includes forming the distal end of inner pins in the first direction to form a gap between the distal end of the inner pins and the mold compound.

14. The method of claim 9, wherein the first direction is in a direction toward the electronic component and the second direction is in a direction toward the mold compound.

15. A method of fabricating electronic devices comprising:
providing an array of leadframes, each leadframe of the array of leadframes having inner pins comprised of a proximate end and a distal end and outer pins comprised of a proximate end, a distal end, and a tie bar connection end, the leadframes being connected to each other via a first tie bar connected to the distal end of the inner and outer pins and a second tie bar connected to the tie bar connection end of the outer pins to form the array;
attaching dies to the proximate end of the inner and outer pins;
forming a mold compound over the dies;
removing the first tie bar from the distal end of the inner and outer pins via a first punch die process;
forming the distal end of the outer pins substantially perpendicular to the proximate end of the inner and outer pins in a first direction;
forming the distal end of the inner pins substantially perpendicular to the proximate end of the inner and outer pins in a second direction, the second direction being opposite to the first direction;
attaching electronic components to an exposed surface of mounting surface portions of the outer pins on a side of the leadframes that is opposite that of the dies;
removing the second tie bar from the tie bar connection end of the outer pins via a second punch die process; and
trimming the tie bar connection end of the outer pins.

16. The method of claim 15, wherein forming a mold compound over the dies includes forming the mold compound over the proximate end of the inner and outer pins that are partially etched.

17. The method of claim 15, wherein attaching electronic components to an exposed surface of mounting surface portions of the outer pins on a side of the leadframes that is opposite that of the dies includes attaching inductors to the exposed surface of the mounting surface portions of the outer pins to contact the distal end of the outer pins.

18. The method of claim 15, wherein forming the distal end of the inner pins substantially perpendicular to the proximate end of the inner and outer pins in a second direction, the second direction being opposite to the first direction includes forming the distal end of the inner pins in the first direction to form a gap between the distal end of the inner pins and the mold compound.

19. The method of claim 15, wherein trimming the tie bar connection end of the outer pins includes trimming the tie bar connection end of the outer pins so that the tie bar connection end of the outer pins is flush with the mold compound.

20. The method of claim 15, wherein the first direction is in a direction toward the electronic component and the second direction is in a direction toward the mold compound.
